(19) United States
(12) Patent Application Publication
(10) Pub. No.: US 2007/0137696 A1
(43) Pub. Date: Jun. 21, 2007

(54) Solar panels, methods of manufacture thereof and articles comprising the same

(76) Inventors: Hans-Joachim Krokoszinski, Muenchen (DE); Oliver Mayer, Muenchen (DE); Joerg Stromberger, Buchenbach (DE); Charles Steven Korman, Niskayuna, NY (US)

Correspondence Address: GENERAL ELECTRIC COMPANY;GLOBAL RESEARCH, PATENT DOCKET RM. BLDG. K1-4A59, NISKAYUNA, NY, 12309, US

(21) Appl. No.: 11/314,539

(22) Filed: Dec. 21, 2005

(51) Int. Cl. H01L 31/00

(52) U.S. Cl. 136/255

(57) ABSTRACT

Disclosed herein are articles for converting electromagnetic radiation to a useful form of energy such as electricity. The articles comprise double-sided photovoltaic cells and/or single-sided photovoltaic cells that can absorb electromagnetic radiation and can convert this radiation into electricity. In one embodiment, the article can comprise opposingly disposed single-sided photovoltaic cells that have a photoactive side and an inactive face respectively. The photovoltaic cells are therefore disposed between two panels or are disposed into a slot that is located on a panel surface that is opposed to the panel surface that is directly impinged by electromagnetic radiation. The articles can be used efficiently as solar panels.

### BACKGROUND

This disclosure relates to solar panels, methods of manufacture thereof and articles comprising the same. More specifically, this disclosure relates to building elements such as roof tiles, window panes, building facades, or the like, having solar energy converters included therein.

Commercially available solar energy converters, such as photovoltaic cells or thermal converters, have high material costs and involve high installation costs that result in a high unit cost per kilowatt-hour of energy generated. Currently available photovoltaic cells generally use silicon, which is expensive. Currently available solar energy converters have a layer of photovoltaic cells disposed upon the upper surface of a panel that is exposed to the sun. The panel is termed a “solar panel”. These photovoltaic cells receive electromagnetic radiation directly from the sun on only a single face and convert this electromagnetic radiation into electrical energy. This arrangement uses a lot of photovoltaic cells and hence a lot of silicon.

For example, a current commercially available solar panel having an irradiated surface area of 1 square meter will use photovoltaic cells uniformly placed on the entire surface of the panel facing the sun. Thus the area of the panel covered with the photovoltaic cells would be about 1 square meter. This results in an extensive use of silicon in current commercially available designs, so that the silicon costs form the predominant share of the panel cost and the resulting energy costs as well.

In addition, recent shortages of the type of silicon used in photovoltaic cells have contributed further to increased material costs. One approach to reducing material costs is to concentrate solar radiation onto an energy converter by using optical surface structuring, such as by Fresnel lens. Such approaches are difficult to implement and have not had sufficient cost/performance benefit to justify penetrating the renewable energy market.

It is therefore desirable to have arrangements for photovoltaic cells that can result in an efficient conversion of electromagnetic radiation to a useful form of energy.

### SUMMARY

Disclosed herein is an article comprising a first panel comprising a slot; wherein the first panel comprises a first surface, a second surface and “n” sides; wherein the first surface and the second surface are opposed to each other and wherein a side has a surface that contacts the first surface and the second surface; where n is a positive integer; and a double-sided photovoltaic cell comprising a first face and a second face disposed in the slot; wherein the double-sided photovoltaic cell is operative to receive electromagnetic radiation from the first panel on the first face and the second face simultaneously.

Disclosed herein too is an article comprising a first panel comprising a first surface, a second surface and “n” sides and having a first slot disposed therein; wherein the slot has an opening to the first surface and wherein the first surface and the second surface are opposed to each other; a second panel comprising a first surface, a second surface and “n” sides; wherein the first surface and the second surface are opposed to each other; wherein a portion of the first surface of the second panel is in intimate overlapping contact with a portion of the second surface of the first panel; where n is a positive integer; and a double-sided photovoltaic cell comprising a first face and a second face disposed in the first slot in the first panel; wherein the double-sided photovoltaic cell is operative to receive electromagnetic radiation from the first panel and the second panel on its first face and its second face simultaneously.

Disclosed herein too is an article comprising a first panel comprising a first surface, a second surface and “n” sides; wherein the first surface and the second surface are opposed to each other; a second panel comprising a first surface, a second surface and “n” sides; wherein the first surface and the second surface are opposed to each other; wherein either a first surface or a second surface of the first panel and the second panel are in a single plane; a double-sided photovoltaic cell disposed between the first panel and the second panel; wherein the double-sided photovoltaic cell has a first face and a second face and wherein the first face contacts the first panel and the second face contacts the second panel.

Disclosed herein too is a method comprising irradiating a panel that comprises a fluorescent dye with incident electromagnetic radiation; absorbing the electromagnetic radiation in the fluorescent dye; re-emitting larger wavelength radiation; wherein the re-emitted radiation has a wavelength that is larger than the wavelength of the incident electromagnetic radiation; irradiating both faces of a double-sided photovoltaic cell with the larger wavelength radiation; and generating an electrical current.

Disclosed herein too is an article comprising a plurality of panels; wherein each panel comprises a first surface, a second surface and “n” sides; wherein the first surface and the second surface are opposed to each other; wherein either the first surface or the second surface of the plurality of panels lies substantially in a single plane; and a double-sided photovoltaic cell or a pair of opposingly disposed single-sided photovoltaic cells disposed between a pair of panels; wherein the photovoltaic cells are operative to absorb electromagnetic radiation from the panels and to convert the electromagnetic radiation to electrical energy.

Disclosed herein too is an article comprising a first panel comprising a first surface, a second surface and “n” sides; wherein the first surface and the second surface are opposed to each other; a second panel comprising a first surface, a second surface and “n” sides; wherein the first surface and the second surface are opposed to each other; wherein either a first surface or a second surface of the first panel and the second panel are in a single plane; and a pair of opposingly disposed single-sided photovoltaic cells disposed between the first panel and the second panel; wherein the opposingly disposed single-sided photovoltaic cells each have a photoactive face and an inactive face; and further wherein the inactive faces are opposingly disposed.

Disclosed herein too is an article comprising a first panel comprising a slot; herein the first panel comprises a first surface, a second surface and “n” sides; wherein the first surface and the second surface are opposed to each other and wherein a side has a surface that contacts the first surface and the second surface; where n is a positive integer; and a pair of opposingly disposed single-sided photovoltaic cells disposed in the slot; wherein the opposingly disposed single-sided photovoltaic cells each have a photoactive face and an inactive face; and further wherein the inactive faces are opposingly disposed.

Disclosed herein too is an article comprising a first panel comprising a first surface, a second surface and “n” sides; wherein the first surface and the second surface are opposed to each other; a second panel comprising a first surface, a second surface and “n” sides; wherein the first surface and the second surface are opposed to each other; wherein either a first surface or a second surface of the first panel and the second panel are in a single plane; and a single-sided photovoltaic cell and a double-sided photovoltaic cell disposed between the first panel and the second panel; wherein the single-sided photovoltaic cell has a photoactive face and an inactive face; and wherein the double-sided photovoltaic cell has two photoactive faces; and further wherein the photoactive face of the single-sided photovoltaic cell and one photoactive face of the double-sided photoactive cell are situated in a manner that renders them operative to receive electromagnetic radiation.

Disclosed herein too is an article comprising a first panel comprising a slot; wherein the first panel comprises a first surface, a second surface and “n” sides; wherein the first surface and the second surface are opposed to each other and wherein a side has a surface that contacts the first surface and the second surface; where n is a positive integer; and a single-sided photovoltaic cell and a double-sided photovoltaic cell disposed in the slot; wherein the single-sided photovoltaic cell has a photoactive face and an inactive face; and wherein the double-sided photovoltaic cell has two photoactive faces; and further wherein the photoactive face of the single-sided photovoltaic cell and one photoactive face of the double-sided photoactive cell are situated in a manner that renders them operative to receive electromagnetic radiation.

Disclosed herein too is a method comprising irradiating a panel with incident electromagnetic radiation; wherein the panel comprises a fluorescent dye; absorbing the electromagnetic radiation in the fluorescent dye; re-emitting larger wavelength radiation; wherein the re-emitted radiation has a wavelength that is larger than the wavelength of the incident electromagnetic radiation; irradiating a photoactive face of a pair of opposingly disposed single-sided photovoltaic cells with the larger wavelength radiation; and generating an electrical current.

### DETAILED DESCRIPTION OF FIGURES

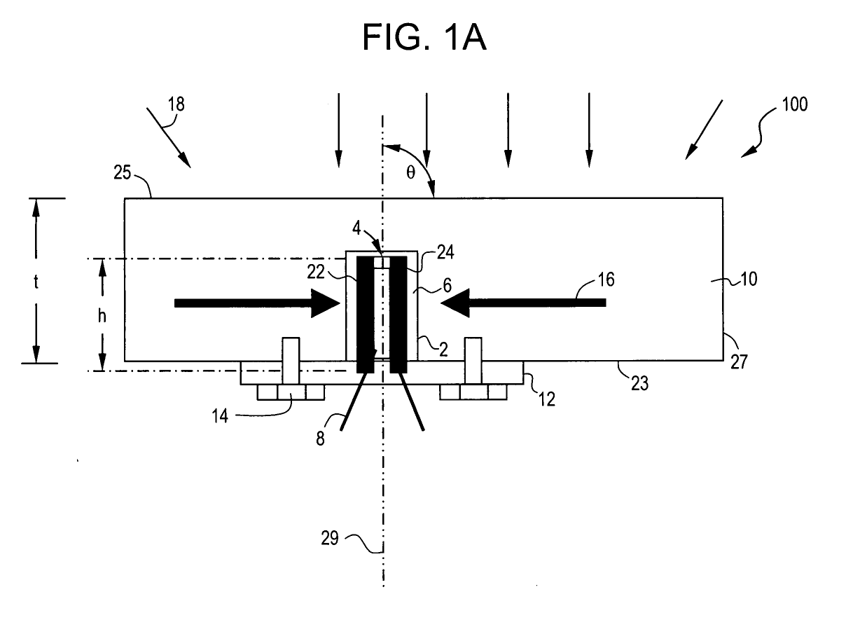

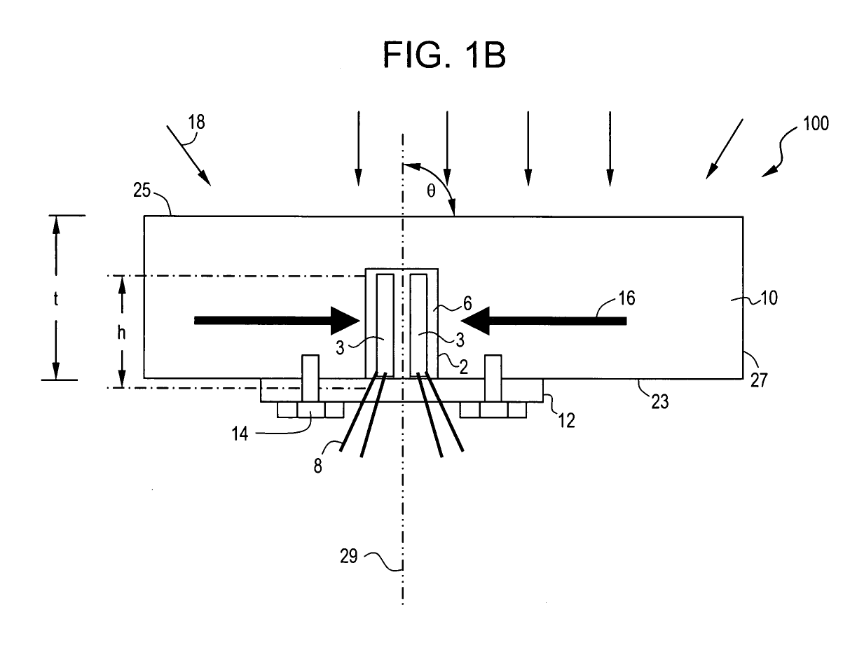

FIG. 1(a) depicts a system 100 for generating electrical energy comprising a panel 10 comprising a plurality of slots 2 into which are disposed a plurality of double-sided photovoltaic cells 4; FIG. 1(b) depicts a system 100 for generating electrical energy comprising a panel 10 comprising a slot 2 into which is disposed a plurality of opposing single-sided photovoltaic cells 3;

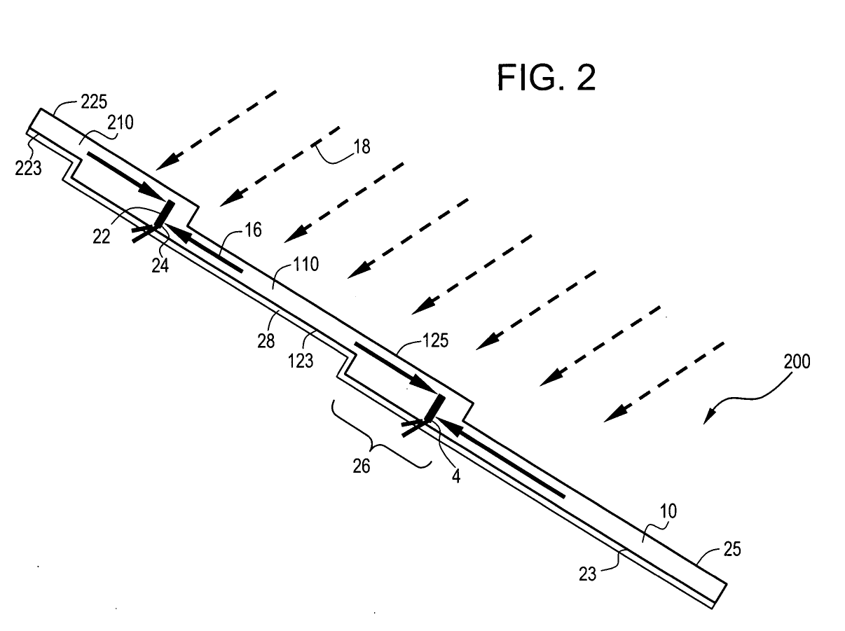

FIG. 2 depicts one exemplary embodiment of a system 200, where a plurality of panels 10 may be fixedly attached to one another. As can be seen in the FIG. 2, the panels are arranged in an overlapping fashion, with a portion of a first panel disposed upon a portion of an adjacent second panel and fixedly attached to it. The photovoltaic cell 4 is disposed in the overlapping portion 26;

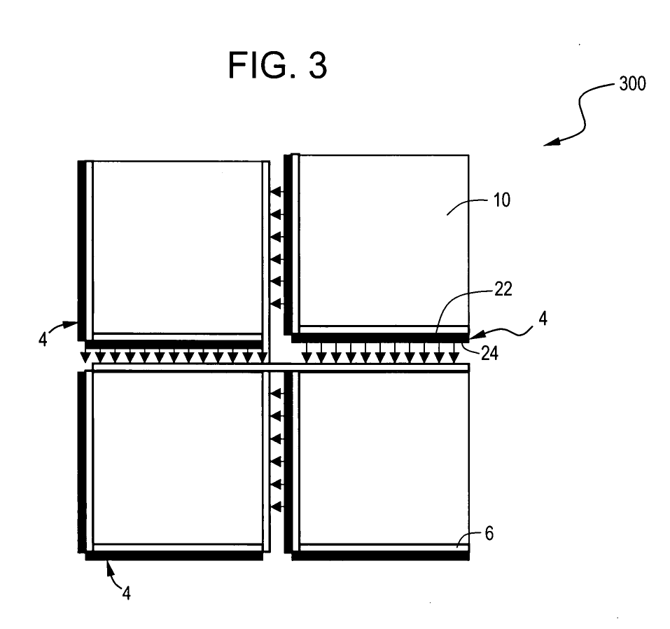

FIG. 3 reflects one exemplary embodiment of a system 300 comprising a plurality of panels 10 having disposed therebetween a photovoltaic cell 4;

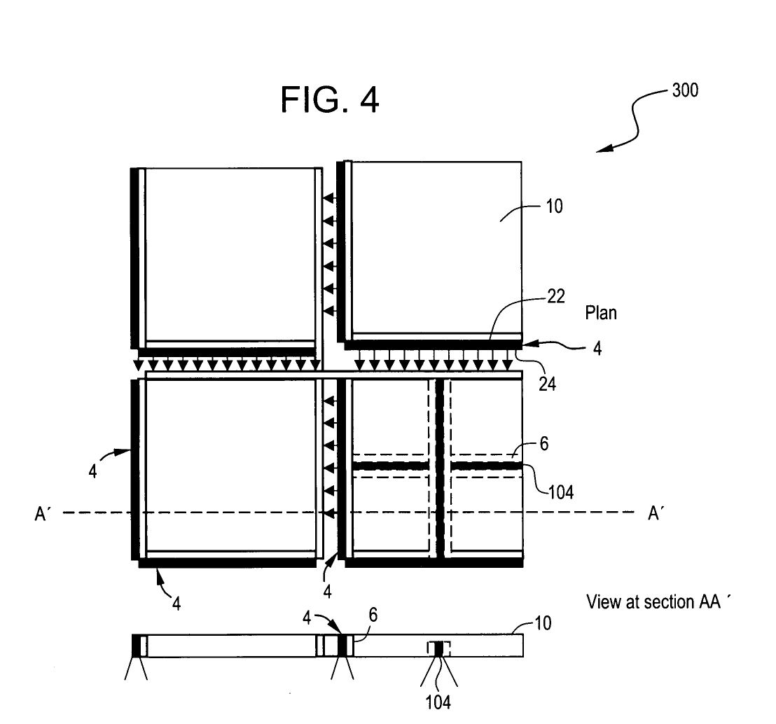

FIG. 4 depicts an exemplary embodiment that combines the embodiment depicted in the FIG. 1(a) with the embodiment depicted in the FIG. 3. In the FIG. 4, as in the FIG. 3, a first photovoltaic cell 4 or a plurality of first photovoltaic cells 4 are disposed at the interface between two separate individual panels 10;

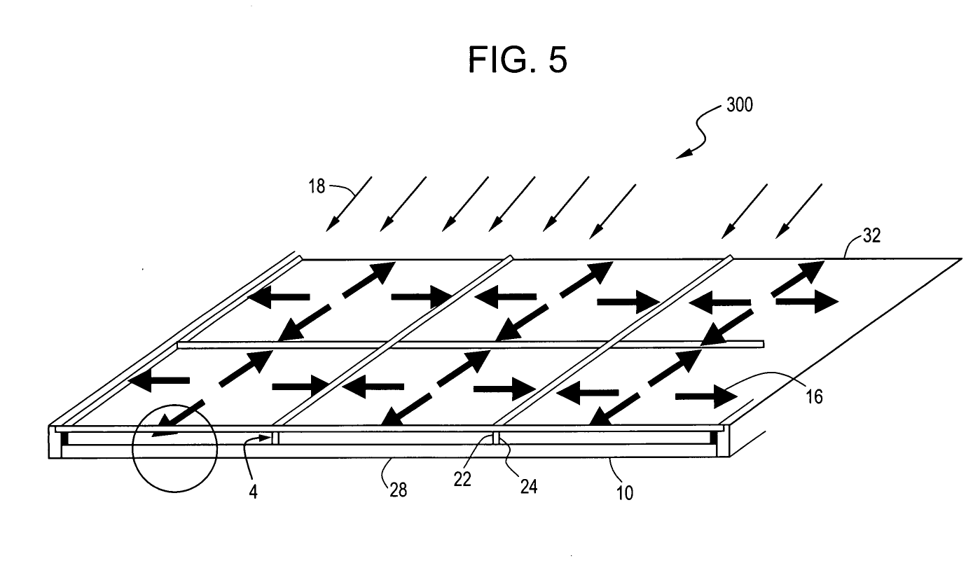

FIG. 5 represents an assemblage 400 comprising a plurality of panels 10 disposed upon a supporting frame that serves as the reflector 28. An adhesive (not shown) can optionally be disposed between the reflector 28 and the plurality of panels 10;

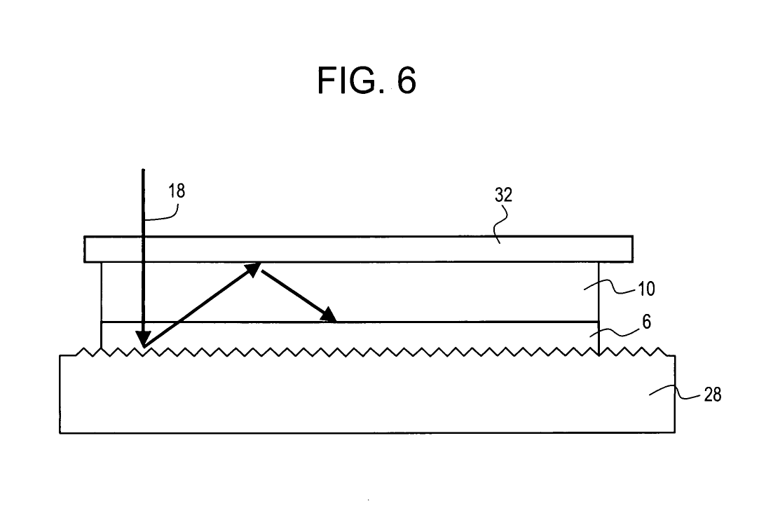

FIG. 6 represents a magnified view of a section of the assemblage 400 represented by the circle in FIG. 5. From the FIG. 6, it may be seen a beam of electromagnetic radiation 18 that is incident upon the panel 10 travels through first the transparent glass panel 32;

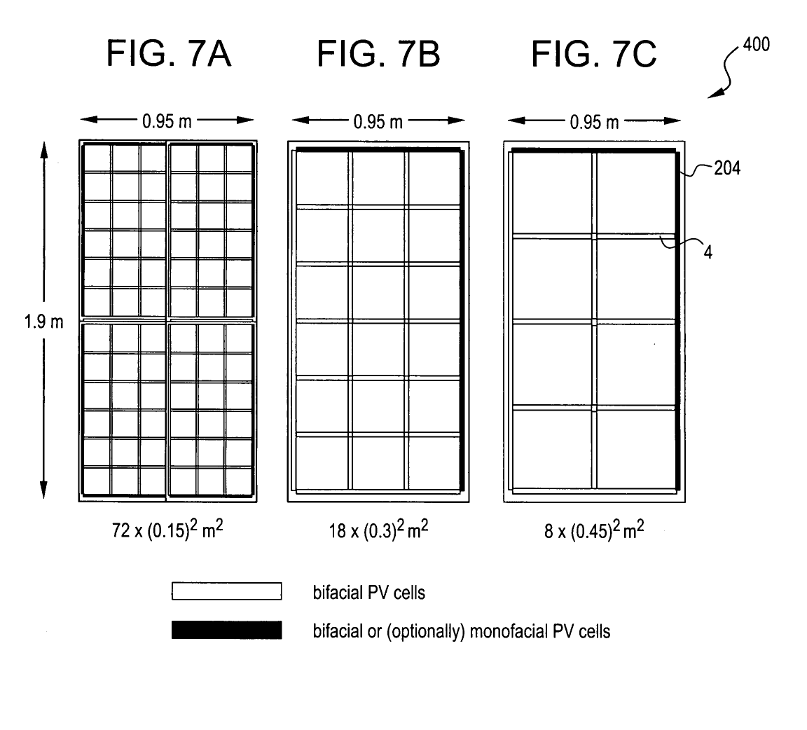

FIG. 7 depicts three systems 400 comprising a plurality of panels 10. Each system 400 has a height of about 1.9 meters (m) and a width of about 0.95 m. FIG. 7(a) depicts a system comprising 72 panels each having an edge of length 0.15 meters, while FIG. 7(b) depicts a system comprising 18 panels each having an edge of length 0.30 meters and FIG. 7(c) depicts a system comprising 8 panels each having an edge of length 0.45 meters;

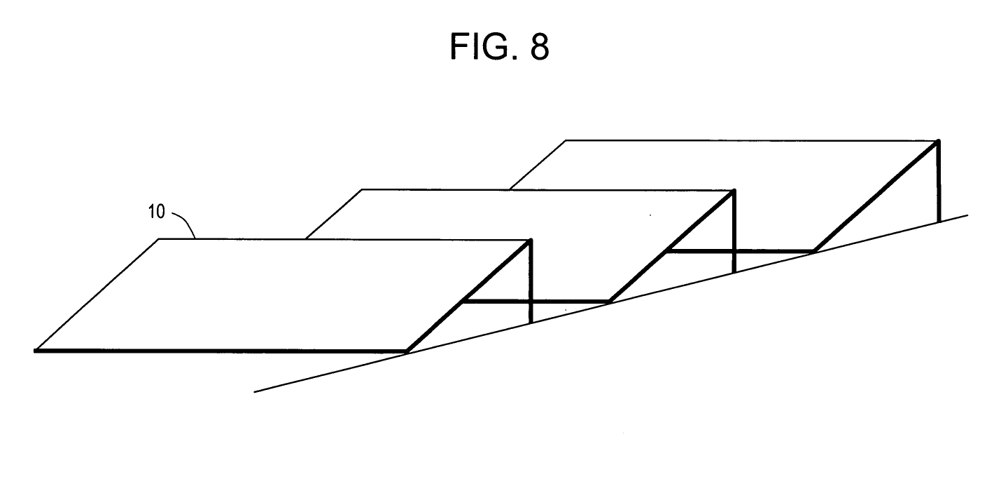

FIG. 8 depicts an exemplary embodiment in which the panels 10 comprising double-sided photovoltaic cells 4 may be configured in a saw tooth configuration for use in green-houses, industrial office space, manufacturing sites, or the like; and

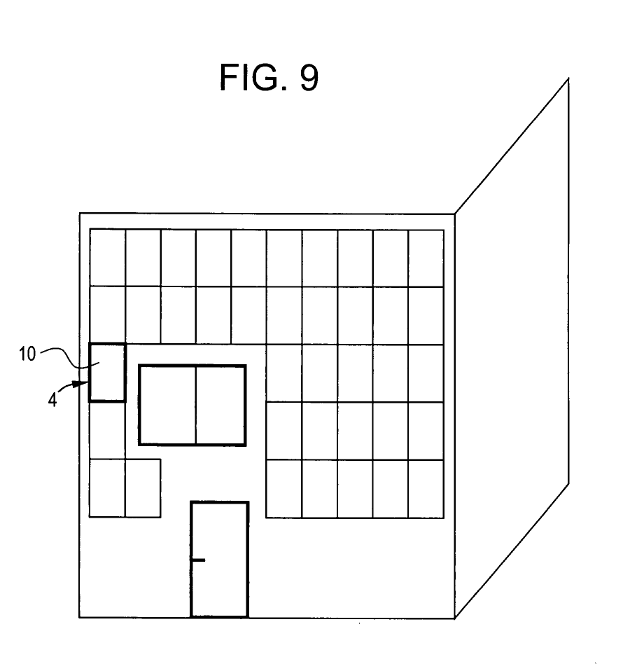

FIG. 9 depicts an exemplary embodiment in which the panels 10 comprising double-sided photovoltaic cells 4 can be used as façades in residential or office buildings.

### DETAILED DESCRIPTION

It is to be noted that the terms “first,” “second,” and the like as used herein do not denote any order, quantity, or importance, but rather are used to distinguish one element from another. The terms “a” and “an” do not denote a limitation of quantity, but rather denote the presence of at least one of the referenced item. The modifier “about” used in connection with a quantity is inclusive of the stated value and has the meaning dictated by the context (e.g., includes the degree of error associated with measurement of the particular quantity). It is to be noted that all ranges disclosed within this specification are inclusive and are independently combinable.

Disclosed herein are panels that use double-sided photovoltaic (PV) cells to convert radiation having a wavelength in the visible frequency range to electrical energy. Disclosed herein too are panels that use opposingly disposed single-sided photovoltaic cells that can convert radiation having a wavelength in the visible frequency range to electrical energy. The photovoltaic cells are disposed in slots or grooves in the panels. The panels are manufactured from a composition that comprises a fluorescent dye and an optically transparent optical polymer or an optically transparent glass. Radiation that is directly incident upon the panels is re-directed to the photovoltaic cells located in the slots or grooves and is converted to electrical energy. The radiation can impinge on both faces of the double-sided cell or on the opposing faces of the pair of single-sided cells and thereby improve the energy conversion efficiency per cell.

It is to be noted that while most of the Figures and the text disclosed herein reference double-sided photovoltaic cells, it is understood that opposingly disposed single-sided photovoltaic cells or a combination of a double-sided photovoltaic cell and a single-sided photovoltaic cell can be used as well. Single sided photovoltaic cells generally have one photoactive face and an inactive face. Double-sided photovoltaic cells have two photoactive faces. The photoactive face can absorb electromagnetic radiation that impinges upon it and facilitates a conversion of this radiation into electricity.

The fluorescence collector (FC) technology is applied for the first time to flat panels comprising photovoltaic cells rather than roof-integrated tile-type of modules. The photovoltaic cells are installed such that their heights “h” as seen in the FIG. 1(a) below are perpendicular to the illuminated surfaces of the panels in which or upon which they are disposed.

As a result of light being absorbed by both faces of a double-sided photovoltaic cell or on the opposing faces of single-sided photovoltaic cells, the power delivered by the cell can be almost doubled. This gain can be used to either increase the electrical power density (power per unit roof area) or to decrease the number of cells (and cost) per unit area while retaining the power density panels that comprise only photovoltaic cells that are subjected to uni-facial (single-sided) illumination.

In one embodiment, the double-sided photovoltaic cell or the opposingly disposed single-sided cells are located in a slot cut in a panel so that radiation can impinge on the photovoltaic cell from both sides. In another embodiment, the double-sided photovoltaic cell or the opposingly disposed single-sided photovoltaic cells can be located between the opposing surfaces of two separate adjacent panels so that radiation can impinge on the photovoltaic cell from both sides. The two separate panels can be disposed upon a supporting frame with the photovoltaic cell(s) disposed between them if desired.

The use of double-sided photovoltaic cells or opposingly disposed single-sided photovoltaic cells is advantageous in that the total amount of installed semiconductor material per watt can be reduced by a factor of up to about 50%, when compared with comparative systems that employ single-sided photovoltaic cells. In addition, the accommodation of the photovoltaic cells in slots enables the pre-mounting, cabling and pre-testing of the cells before final assembly into the panel. The enclosure and sealing of the photovoltaic cells in the slots also protects them from mechanical stress and chemical attack by gases and liquids.

With reference now to the FIG. 1(a), a system 100 for generating electrical energy comprises a panel 10 (of thickness “t”) that comprises a plurality of slots 2 into which are disposed a plurality of double-sided photovoltaic cells 4. The photovoltaic cell 4 has a height “h” and is in electrical communication via an electrical lead 8 with an electrical load (not shown) that consumes electricity generated by the photovoltaic cell 4. While the slot 4 may be cut at any location in the thickness “t” of the panel to accommodate the photovoltaic cells 4, the electrical leads 8 generally emerge from a surface of the panel 10 that is opposed to a surface that is directly illuminated by the source of electromagnetic radiation 18. The electrical leads 8 can also emerge from the surface of the panel 10 that is directly exposed to the sun if desired because of spatial limitations or for engineering reasons. The electromagnetic radiation 18 emerging from the source is generally ultraviolet radiation, visible radiation or infrared radiation. The source can be any light source such as the sun, a incandescent bulb, a fluorescent lamp, a sodium or mercury vapor lamp, or the like. Solar radiation is the desired radiation for efficacious operation of the systems 100 and other systems described herein.

While all the figures in this disclosure show one set of electrical leads emanating form the surface of the panel that is opposed to the directly illuminated surface, it is indeed possible to have photovoltaic cells that comprise electrical leads that emanate from both surfaces of the panel. The electrical leads are generally in electrical communication with an electrical bus that is further in electrical communication with a load. The leads along with the bus are disposed so as not to interfere with the incident electromagnetic radiation.

It is to be noted that the height “h” of the photovoltaic cell is measured in a direction that is perpendicular to the surface of the panel 10 upon which electromagnetic radiation is incident.

As can be seen in the FIG. 1(a), an adhesive 6 is disposed on the opposing faces of the photovoltaic cell 4. The adhesive 6 has the same refractive index as the panel 10, so as to minimize any reflection, refraction or diffraction incident light away from the sides of the photovoltaic cell 4. In one embodiment, as depicted in the FIG. 1(a), the photovoltaic cell 4 may be fixedly attached via a washer 12 and a bolt 14 with the panel 10. In another embodiment, not depicted in the FIG. 1(a), the photovoltaic cell 4 may be matingly engaged with the panel 10 with the adhesive providing the necessary bonding to maintain the photovoltaic cell in position.

The location of the screw holes in the panel 10 can be varied so that the position of the photovoltaic cell with respect to the center of the slot 2 can be adjusted. The use of the adhesive 6 serves to protect the photovoltaic cells from mechanical stress, abrasion and degradation due to exposure to chemicals.

The panel 10 generally has two opposing surfaces, a first surface 23 and a second surface 25 that are connected by one or more surfaces 27 that comprise the sides of the panel 10. The panel can have n sides where n is a positive integer having values of 3 or greater. The first surface 23 and the second surface 25 can be inclined with respect to each other or can be parallel to each other. In an exemplary embodiment, the first surface 23 of the panel and the second surface 25 of the panel are parallel to each other. The one of more surfaces 27 that constitute the sides of the panel can be perpendicular to the first surface 23 and/or the second surface 25. In one embodiment, an axis of the photovoltaic cell 29 and the slot 2 is inclined at an angle θ to the first surface 23 and/or the second surface 25. The angle θ can have a value of about 5 to about 90 degrees. In an exemplary embodiment depicted in the FIG. 1(a), the angle θ is equal to 90 degrees.

As can be seen in the FIG. 1(a), the slot 2 has an opening onto the first surface 23. The second surface 25 is the surface that receives impinging electromagnetic radiation prior to any other surfaces in the panel 10. The radiation is absorbed and re-emitted by the fluorescent dyes present in the panel 10. The re-emitted radiation impinges on the first face and the second face of the photovoltaic cell generating an electrical current that can be used for a multitude of purposes.

FIG. 1(b) is an exemplary depiction of a panel that comprises two opposingly disposed single-sided photovoltaic cells disposed in the slot 2. The opposingly disposed single-sided photovoltaic cells are disposed in the slot using an adhesive 6. A layer of adhesive 6 may also be disposed between the two opposingly disposed single-sided photovoltaic cells. In the FIG. 1(b) it is to be noted that the single-sided cells are disposed so as to have their respective photoactive faces facing the incident radiation from the panel, while the inactive faces of the respective photovoltaic cells face each other. This configuration of the single-sided cells where the inactive faces of the respective photovoltaic cells face each other is termed “opposingly disposed”.

In one embodiment, a single-sided photovoltaic cell and a double-sided photovoltaic cell may be disposed in a single slot or between two panels. Radiation from the panel can impinge on the photoactive faces of the single-sided cell and the double-sided cell. In another embodiment, two or more double-sided photovoltaic cells can be disposed next to each other in a single slot or between two panels.

In one embodiment, the double-sided cells or the opposingly disposed single-sided cells can be prepackaged into a device that can be inserted into a slot in a panel 10 or disposed in between two panels. The device can comprise two optically transparent modular glass components or two optically transparent plastic components having a space between them to accommodate the photovoltaic cell. The optically transparent components are opposingly disposed and can be matingly engaged so that the photovoltaic cell can be inserted into a space between the two components prior to matingly engaging the two components. The components have openings for the electrical leads of the photovoltaic cells. The leads may emanate from the upper surface and the lower surface of the device and can be in electrical communication with an electrical bus that criss-crosses the first surface 23 and the second surface 25 of the panel 10. The electrical bus is generally disposed so as not to interfere with light incident upon the panels. The prepackaged device can be optionally pre-tested and “dropped into” a slot in the panel 10 when desired or alternatively disposed between two panels.

The panel 10 is generally manufactured from a composition that comprises an optically transparent organic polymer or an optically transparent glass having a fluorescent dye dispersed therein. The organic polymers can be thermoplastics, thermosets, or a combination of thermoplastics with thermosets. The organic polymer can comprise a homopolymer, a copolymer such as a star block copolymer, a graft copolymer, an alternating block copolymer or a random copolymer, an ionomer, a dendrimer, or a combination comprising at least one of the foregoing. The organic polymer can also be a blend of polymers, copolymers, terpolymers, or the like, or a combination comprising at least one of the foregoing.

Examples of optically transparent organic polymers are polycarbonate (PC), polystyrene, copolyestercarbonate, polyetherimides, polyesters such as, for example, polyethylene terephthalate (PET), polybutylene terephthalate (PBT), poly(1,4-cyclohexane-dimethanol-1,4-cyclohexanedicarboxylate) (PCCD), poly(trimethylene terephthalate) (PTT), poly(cyclohexanedimethanol-co-ethylene terephthalate) (PETG), poly(ethylene naphthalate) (PEN), poly(butylene naphthalate) (PBN); polyarylates, polyimides, polyacetals, polyacrylics, polyamideimides, polyacrylates, polymethacrylates such as, for example, polymethylacrylate, or polymethylmethacrylate (PMMA); polyurethanes, or the like, or a combination comprising at least one of the foregoing polymers.

Examples of blends of the organic polymers are polymeric mixtures derived from mixing polycarbonate and polyesters are PC-PCCD, PC-PETG, PC-PET, PC-PBT, PC-PCT, PC-PCTG, PC-PPC, PC-PCCD-PETG, PC-PCCD-PCT, PC-PPC-PCTG, PC-PCTG-PETG, PC-polyarylates, or the like, or a combination comprising at least one of the foregoing polymeric mixtures.

Examples of optically transparent glasses are silica, alumina, titania, or the like, or a combination comprising at least one of the foregoing glasses. In one exemplary embodiment, low temperature glasses can be used in the panel.

The fluorescent dyes are generally those that can absorb radiation in the visible wavelengths and emit the radiation at a wavelength that is different from that of the absorbed radiation. In general, the wavelength of the emitted radiation is larger than the wavelength of the absorbed radiation. This ability to emit radiation having a wavelength that is longer than that of the absorbed radiation is termed a “Stokes shift”.

It is generally desirable for the fluorescent dye to absorb electromagnetic radiation in the ultraviolet and visible regions of the electromagnetic spectrum and to re-emit this radiation in the near infra-red region of the electromagnetic spectrum. Emission of electromagnetic radiation in the near infra-red region of the electromagnetic spectrum leads to a better correspondence between the wavelength of emitted radiation and the band-gap of the photovoltaic cell 4.

In one embodiment, a plurality of fluorescent dyes can be used to facilitate a step-wise approach to re-emitting (absorbed ultraviolet and visible electromagnetic radiation) in the near infra-red regions of the electromagnetic spectrum. In this approach, a series of fluorescent dyes each of which absorb and re-emit electromagnetic radiation at gradually increasing wavelength sizes is used in the panel. Thus for example, a first dye absorbs radiation at a first wavelength and re-emits this radiation at a second wavelength that is larger than the first wavelength. A second dye in the same panel will absorb the radiation at the second wavelength and re-emits this radiation at a third wavelength that is larger than the second wavelength. In this step-wise fashion, the wavelength of the radiation that impinges on the faces of the photovoltaic cell is converted to being substantially in the near infra-red region of the electromagnetic spectrum.

The fluorescent dyes thus absorb light from a plurality of directions and emit light at different wavelengths in the panel. As can be seen in the FIG. 2, this emitted light impinges on the respective faces of the photovoltaic cell and is converted into electrical energy. In one embodiment, the fluorescent dyes that are used in a particular panel can be selected based upon aesthetic effects in addition to the amount of light emitted.

Fluorescent dyes for a particular panel can therefore be selected based upon a desired appearance or color of a building element, a desired light absorption characteristic of the building element, a desired shadowing characteristic, or combinations thereof. While the fluorescent dyes add certain aesthetic features to the panel, other dyes and additives can be added solely for aesthetic reasons if desired.

The fluorescent dyes can comprise an organic dye or an inorganic dye and can be in the form of particles, quantum dots, or a combination of particles and quantum dots. The organic fluorescent dyes can be polymeric dyes. The fluorescent dye can be in the form of a liquid prior to mixing it with the organic polymer or the glass.

A quantum dot generally comprises an inorganic material, which becomes excited and emits light. Quantum dots advantageously have narrower bandwidths of radiation absorption and emission than the particles. In one embodiment, the quantum dots can comprise phosphors. Examples of quantum dots that comprise phosphors are zinc oxide (ZnO); zinc sulfide (ZnS); zinc selenide (ZnSe); zinc sulfide activated cadmium (ZnS:Cd); zinc sulfide activated silver (ZnS:Ag); yttrium aluminum garnet activated with cerium (Y₃Al₅O₁₂:Ce); yttrium orthosilicate single crystal activated with cerium (Y₂SiO₅:Ce); europium activated barium magnesium aluminate (Ba, Eu)MgAl₁₀O₁₇; europium activated strontium barium calcium halo phosphate (Sr, Ba, Ca)₁₀(PO₄)₆Cl₂:Eu; cerium and terbium activated magnesium aluminate (Ce, Tb)MgAl₁₁O₉; lanthanum, cerium or terbium activated phosphate (La, Ce, Tb)PO₄; europium activated yttrium oxide (Y, Eu)₂O₃, or the like, or a combination comprising at least one of the foregoing phosphors.

Other examples of quantum dots that can be used are cadmium selenide, cadmium sulfide, or the like, or a combination comprising at least one of the foregoing quantum dots.

Examples of suitable fluorescent dyes that can be used in the panels are 3-3′-diethyloxycarbocyanine-iodide, cresyl violet 670 perchlorate, anthranones and their derivatives; anthraquinones and their derivatives; croconines and their derivatives; monoazos, disazos, trisazos and their derivatives; benzimidazolones and their derivatives; diketo pyrrole pyrroles and their derivatives; dioxazines and their derivatives; diarylides and their derivatives; indanthrones and their derivatives; isoindolines and their derivatives; isoindolinones and their derivatives; naphtols and their derivatives; perinones and their derivatives; perylenes and their derivatives such as perylenic acid anhydride or perylenic acid imide; ansanthrones and their derivative; dibenzpyrenequinones and their derivatives; pyranthrones and their derivatives; bioranthorones and their derivatives; isobioranthorone and their derivatives; diphenylmethane, and triphenylmethane, type pigments; cyanine and azomethine type pigments; indigoid type pigments; bisbenzoimidazole type pigments; azulenium salts; pyrylium salts; thiapyrylium salts; benzopyrylium salts; phthalocyanines and their derivatives, pryanthrones and their derivatives; quinacidones and their derivatives; quinophthalones and their derivatives; squaraines and their derivatives; squarilyiums and their derivatives; leuco dyes and their derivatives, deuterated leuco dyes and their derivatives; leuco-azine dyes; acridines; di-and tri-arylmethane, dyes; quinoneamines; o-nitro-substituted arylidene dyes, aryl nitrone dyes, or the like, or a combination comprising at least one of the foregoing. Exemplary fluorescent dyes are perylenes and their derivatives, commercially available as LUMOGEN® from BASF.

As noted above, two or more fluorescent dyes may be included in the composition used for manufacturing the panel. It is generally desirable for each fluorescent dye to absorb a different portion of the incident spectrum of electromagnetic radiation. Since each dye absorbs a portion of the spectrum of electromagnetic radiation a larger portion of the incident radiation can be captured and converted into usable energy. While different portions of the incident electromagnetic radiation are absorbed by the respective dyes, it is possible for a portion of the electromagnetic radiation to be absorbed by both the fluorescent dyes.

The panel 10 can have any desired shape. The panel 10 may have surfaces that are flat or curved. The edges of the panel 10 can be linear or curvilinear in a direction measured perpendicular to the direction in which the thickness “t” is specified. In an exemplary embodiment, the edges of the panel are linear. The geometry of the cross-sectional area of the panel 10 measured in at least one direction perpendicular to the thickness “t” can be square, rectangular, or polygonal if desired.

In one embodiment, the panel 10 can have “n” sides, where n is a positive integer of 3 or greater. Photovoltaic cells (both double-sided and opposingly disposed single-sided photovoltaic cells) can be disposed on each of the “n” sides of the panel if desired. Alternatively, the photovoltaic cells can be disposed on “n-1, n-2, n-3, n-4 or n-5 sides if desired. In one embodiment, each panel used in a given system has photovoltaic cells disposed on only two of the sides of the panel.

It is desirable to optimize the distance between the rows of successive photovoltaic cells 4. If the distance between successive rows of photovoltaic cells 4 is too small then collected light between two laminates will be lower than optimum and if the distance becomes too large then the losses of radiation from the panel 10 will lead to a suboptimal performance. In one embodiment, the distance between successive rows of photovoltaic cells 4 in a given system 10 can be determined by the dimensions of individual panels 10. As disclosed herein the “distance between rows of successive photovoltaic cells” refers to rows of photovoltaic cells that are located on opposite sides (edges) of a panel and not to the distance between two rows of opposingly disposed single-sided cells that lie in a single slot.

If the panel 10 has a square cross-sectional area (measured in a direction perpendicular to the thickness), then it is desirable for the length of the edge (side) of the square to be about 0.10 to about 0.70 meters. In one embodiment, it is desirable for the length of the side of the square to be about 0.15 to about 0.5 meters. In another embodiment, it is desirable for the length of the side of the square to be about 0.2 to about 0.4 meters. In yet another embodiment, it is desirable for the length of the side of the square to be about 0.25 to about 0.35 meters. The length of the side of the square will determine the distance between successive rows of photovoltaic cells 4.

The thickness of the panel 10 is about 3 to about 100 millimeters. In one embodiment, the panel 10 has a thickness of about 3.5 to about 50 millimeters. In another embodiment, the panel 10 has a thickness of about 4 to about 20 millimeters. An exemplary thickness is about 4 to about 10 millimeters.

It is generally desirable to use the fluorescent dyes in an amount of about 0.01 to about 1 weight percent (wt %), based on the total weight of the composition used to manufacture the panel. In one embodiment, it is desirable to use the fluorescent dyes in an amount of about 0.05 to about 0.5 weight percent (wt %), based on the total weight of the composition used to manufacture the panel. In another embodiment, it is desirable to use the fluorescent dyes in an amount of about 0.06 to about 0.1 weight percent (wt %), based on the total weight of the composition used to manufacture the panel.

In one embodiment, about 5 to about 25 percent of the energy contained in the electromagnetic radiation that irradiates the panels is incident upon the edges (after absorption and re-emission by the fluorescent dyes) of the panel where it is efficiently absorbed by the photovoltaic cells and converted into electricity. In another embodiment, about 10 to about 15 percent of the energy contained in the electromagnetic radiation that irradiates the panels is incident upon the edges of the panel where it is efficiently absorbed by the photovoltaic cells and converted into electricity. In another embodiment, in order to absorb as much incident radiation as possible, more than one dye is put into the panel.

In one embodiment, the dyes used in the fluorescence collector have a quantum efficiency of greater than or equal to about 90%. In another embodiment, the dyes used in the fluorescence collector have a quantum efficiency of greater than or equal to about 95%. In another embodiment, the dyes used in the fluorescence collector have a quantum efficiency of about 100%.

In addition to the fluorescent dyes, other additives may be included in the composition used to manufacture the panels. Examples of such additives are viscosity modifiers, mold release agents, UV absorbers, anti-oxidants, anti-ozonants, thermal stabilizers, or the like, or a combination comprising at least one of the foregoing additives.

The adhesive 6 can comprise a polymer. It is desirable for the adhesive to be optically transparent and to have the same refractive index as the panel, so as to minimize loss of radiation due to reflection, refraction, or diffraction. Examples of suitable organic polymers that can be used as adhesives are epoxies, polysiloxanes, phenolics, polyurethanes, or the like, or a combination comprising at least one of the foregoing adhesives. In one exemplary embodiment, elastomeric adhesives that have hot melt properties can be to provide support for the matingly engaged surfaces of the slot 2 and those of the photovoltaic cell 4.

With reference now again to the FIG. 1(a), the photovoltaic cell comprises a first face 22 and a second face 24. Emitted radiation 16 from the fluorescent dyes in the surrounding panel is concentrated towards the first face 22 and the second face 24. The net effect is a concentration of the light to several multiples of the natural irradiation. The photovoltaic cell converts about one quarter of the irradiated power, and such cells use radiation from only a small fraction of the irradiated surface area of the panel (about 1/30 of the surface area of the panel). Thus, the photovoltaic cell area needed per watt of produced electrical power is reduced thereby leading to a substantial reduction in material costs. The photovoltaic cell 4 may be disposed at the top, the bottom or the center of the panel 10 along its thickness

Commercially available types of bifacial photovoltaic cells may be used in the system 100. In one embodiment, bifacial photovoltaic cells may comprise cadmium sulfide/cadmium telluride/zinc telluride cells, indium-gallium-phosphorus/gallium arsenide cells, copper-indium-gallium-selenide cells, or the like, that can collect the incident radiation and convert it to electrical energy. In an exemplary embodiment, a bifacial photovoltaic cell comprising silicon can be used in the system 100. Monocrystalline silicon photovoltaic cells can also be used. A commercially available example of a bifacial photovoltaic cell that comprises silicon is SLIVER™ from Origin Energy Solar. The SLIVER™ photovoltaic cell comprises mono-crystalline silicon, which is cut perpendicular to the wafer surfaces. Since the sum of the cross-sectional areas of the silicon in the photovoltaic cell is greater than the wafer's top surface, it increases the illuminated area per silicon wafer.

FIG. 2, depicts one exemplary embodiment of a system 200, where a plurality of panels may be fixedly attached to one another. As can be seen in the FIG. 2, the panels are arranged in an overlapping fashion, with a portion of a first panel disposed upon a portion of an adjacent second panel and fixedly attached to it. The photovoltaic cell 4 is disposed in the overlapping portion 26. Each overlapping portion 26 of panels comprises a slot 2 having a photovoltaic cell 4 or a plurality of photovoltaic cells 4 disposed therein. The plurality of photovoltaic cells may be connected in series or in parallel. The photovoltaic cell 4 may be disposed at any location in the overlapping portion 26 of the panels. An exemplary location is in the center of the overlapping portion 26 of the panels. As can be seen in the FIG. 2, emitted radiation from the fluorescent dye in the panels is concentrated on the faces 22 and 24 of each photovoltaic cell providing the cell with an effective amount of radiation that can be converted to electricity. In one embodiment, one or more double-sided photovoltaic cells can be disposed in the slot 2 located in the overlapping portion of the panels. In another embodiment, two opposingly disposed single-sided photovoltaic cells may be disposed in the slot 2 in the overlapping portion of the panels.

In the FIG. 2, the system 200 comprises a plurality of panels comprising a first panel 10, a second panel 110, a third panel 210, and so on, wherein each panel having a first side and a second side are arranged such that a portion of the first side of one panel overlaps with the second side of another panel. For example, the first panel 10 has a first side 23 and a second side 25, while the second panel 110 has a first side 123 and a second side 125. As can be seen in the FIG. 2, the first sides of the respective panels comprise slots that are configured to receive the double-sided photovoltaic cell, while the second sides receive direct impinging electromagnetic radiation 18. The first side 123 of the second panel 110 overlaps with the second side 25 of the first panel 10 to create an overlapping portion 26. It is generally desirable to have the slot 2 located in the overlapping regions of the two panels.

The panels may be monolithic, i.e., they can be injection molded as a single piece. In one embodiment, two panels may be molded separately and fused together to form the overlap. The overlap may be formed by bonding together the first panel 10 with the second panel 110. In one embodiment, the first panel 10 and the second panel 110 may be fixedly attached. Fixedly attached includes permanent fixing such as fusing the panels together by using a hot melt adhesive, bolting them together, pressing them together under heat and pressure, or the like.

In another embodiment, the first panel 10 and the second panel 110 may be matingly engaged. Matingly engaged includes a temporary fixing that can be removed when desired, such as, for example, a dove tail joint, a mortise and tenon joint, or using a dowel to promote an overlap between the first and the second panel 10.

As can be seen in the FIG. 2, as a result of the arrangement, electromagnetic radiation from both the first panel and the second panel impinges on both faces of the photovoltaic cell 4, thus permitting a more efficient functioning of the cell.

In one exemplary embodiment, depicted in the FIG. 2, the panels 10, 110, 210, and so on, may be optionally disposed upon a reflective layer 28. The reflective layer 28 is disposed on a surface of the panel that is opposed to the surface that is directly exposed to electromagnetic radiation. The reflective layer 28 reflects any radiation that may escape from the panel back into the panel, so that it can be absorbed and emitted towards the photovoltaic cell 4. In one embodiment, the reflective layer 28 can comprise a coating of silver paint. In another embodiment, the reflective layer 28 can comprise a reflective device such as a mirror.

As noted above and as depicted in the FIG. 3, the photovoltaic cell or plurality of photovoltaic cells can be placed between two opposing surfaces of two independent panels. As noted above, the photovoltaic cells can be double-sided photovoltaic cells or can be opposingly disposed single-sided photovoltaic cells. The remaining portion of the discussion on FIG. 3, will, however, focus on double-sided photovoltaic cells. In one embodiment, the panels (having photovoltaic cells disposed upon the periphery of the panels) can be disposed upon a supporting frame if desired. In another embodiment, the panels can be glued together using the adhesive 6. In other words, the adhesive 6 provides the desired support to maintain the panels 10 in a selected plane. FIG. 3 reflects one exemplary embodiment of a system 300 comprising a plurality of panels 10 having disposed therebetween a photovoltaic cell 4.

FIG. 3 depicts the panels 10 separated by a distance (only for purposes of demonstrating to the viewer the arrangement of the panels 10, the adhesive 6 and the photovoltaic cell 4), with the photovoltaic cells 4 and the adhesive 6 disposed between the respective panels. As described above, an adhesive 6 is disposed between the surface of the panel 10 that contacts the photovoltaic cell 4 and the faces 22 and 24 photovoltaic cell 4. Arrows are shown in the FIG. 4 to depict the direction in which pressure can be applied to merge the panels to form the system 300. In an exemplary embodiment, a plurality of photovoltaic cells 4 are disposed between the opposing surfaces of the neighboring panels 10.

In the embodiment depicted in the FIG. 3, the photovoltaic cells 4 can be disposed on one or more edges of a four-sided panel 10. In another embodiment, the photovoltaic cells 4 can be disposed on two or more edges of a four-sided panel 10. In another embodiment, the photovoltaic cells 4 can be disposed on three edges of a four-sided panel 10. In yet another embodiment, the photovoltaic cells 4 can be disposed on all edges of a four-sided panel 10.

FIG. 4 depicts an exemplary embodiment that combines the embodiments depicted in the FIG. 1(a) as well as the embodiment depicted in the FIG. 3. In the FIG. 4, as in the FIG. 3, a first photovoltaic cell 4 or a plurality of first photovoltaic cells 4 are disposed at the interface between two separate individual panels 10. In the FIG. 4, the photovoltaic cells can be double-sided photovoltaic cells or opposingly disposed single-sided cells. However, the following discussion will be focused on double-sided photovoltaic cells.

FIG. 4 also shows a second photovoltaic cell or a plurality of second photovoltaic cells 104 disposed in slots 2 that are cut into each respective panel 10 if desired. As shown in the FIG. 5, the photovoltaic cells 4 that are disposed in the slots are represented by dotted lines. A cross-sectional view taken along line AA′ depicts a first photovoltaic cell 4 disposed along the outer perimeter of the panel 10 and a second photovoltaic cell 104 disposed in a slot 2 that is disposed within the thickness of the panel 10.

FIG. 5 represents an assemblage 400 comprising a plurality of panels disposed upon a supporting frame that serves as the reflector 28. Each panel 10 in the plurality of panels comprises a first surface and a second surface. The panels are arranged such that either the first surface and/or the second surface for each panel lie in substantially the same plane. The first surface and the second surface of each panel can be parallel if desired. In an exemplary embodiment, the first and second surfaces are parallel. The photovoltaic cell is arranged between panels such that the first and second faces of the photovoltaic cell are perpendicular to the first and second surfaces of the plurality of panels.

An adhesive 6 (not shown) can optionally be disposed between the reflector 28 and the plurality of panels. An optional optically transparent panel 32 may also be used to provide support for the plurality of panels 10. The optically transparent panel 32 is disposed upon the plurality of panels 10 on the surface that receives electromagnetic radiation 18 directly. The panel 32 provides protection to the panel 10 as well as the photovoltaic cells. The panel 32 may comprise a glass or an organic polymer. The organic polymer may be the same or different from the organic polymer of the panel 10. The assemblage 400 comprises photovoltaic cells or a plurality of photovoltaic cells disposed along the perimeter of each panel 10. While the photovoltaic cells in this embodiment are depicted as being double-sided, they can be opposingly disposed single-sided photovoltaic cells if desired. The photovoltaic cells 4 are thus disposed between opposing surfaces of the panels 10. As can be seen from the FIG. 5, the radiation 16 emitted from the fluorescent dyes is directed towards the photovoltaic cells 4 located at the periphery of the panels 10. The radiation is incident upon the faces 22 and 24 of the panels 10 and is converted into electricity by the photovoltaic cells.

FIG. 6 represents a magnified view of a section of the assemblage 400 represented by the circle in FIG. 5. From the FIG. 6, it may be seen a beam of electromagnetic radiation 18 that is incident upon the panel 10 travels first through the transparent glass panel 32. A portion of the beam will be absorbed by fluorescent dyes present in the panel 10, while the unabsorbed portion of the beam will travel through the panel as well as the optically transparent adhesive 6. The beam is then reflected back into the panel from the reflective surface 28. The reflective surface 28 may have a structure that is designed to maximize reflection into the panel 10. In one embodiment, as seen in the FIG. 6, the reflecting surface has a serrated or triangular structure to improve reflection of incident light into the panel 10. In this manner, most of the radiation incident upon the glass panel 32 and the panels 10 is absorbed by the fluorescent dyes present in the panel 10 and are concentrated towards the faces 22 and 24 of the double-sided photovoltaic cells.

The size of the panels 10 (for a given thickness of the plate and a given dye and dye concentration) is determined by maximizing the irradiation (and with it the electrical power) of all photovoltaic cells 4 on the periphery of the panels 10. If the size of each panel 10 is too small, then the amount of silicon at its edges (and hence cost) will be too high for the amount of light collected. On the other hand, if the size of each panel 10 is too large, then the losses inside the panel 10 will lead to a suboptimal collector efficiency and, hence, low system efficiency.

Exemplary numerical calculations have shown that for a system comprising a panel 10 having a square cross-sectional area (measured in a direction perpendicular to the thickness t) with each edge having a length of 0.3 meters and double-sided photovoltaic cells 4 having a height “h” of 4 millimeters, the total area of the double-sided photovoltaic cells 4 is only 1.33%, per side (i.e. 1/75) of the illuminated area of the panel 10. For a panel equipped with photovoltaic cells on two edges (e.g., as depicted in the FIG. 4) the area is of the photovoltaic cells is 2.66% of the total surface area of the panel that is exposed to incident electromagnetic radiation. For a panel equipped with photovoltaic cells on four edges, the total area upon which solar energy can impinge on the photovoltaic cells is 1.33×4=5.3% of the total surface area of the panel that is exposed to incident electromagnetic radiation.

If panels having bifacial cells disposed on two sides adjacent to each other are joined together to form a system as depicted in the FIG. 5, the total silicon area remains at 2.66% in addition to the silicon used in the outer circumferential edge area 204 (as seen in the FIG. 7c). However, such a panel has a capacity to generate the same amount of electricity as comparative panels with photovoltaic cells disposed on four sides of each panel.

In one embodiment, a panel having double-sided photovoltaic cells disposed on 4 sides can generate an amount of electrical energy greater than or equal to about 50 Watts/square meter (W/m²). In another embodiment, the panel can generate an amount of electrical energy greater than or equal to about 60 W/m². In yet another embodiment, the panel can generate an amount of electrical energy greater than or equal to about 70 W/m². In yet another embodiment, the panel can generate an amount of electrical energy greater than or equal to about 90 W/m².

As double-sided photovoltaic cells 4 are commercially available with 20% average (full spectrum) efficiency on both faces 22 and 24 and the Stokes shift towards larger wavelengths (e.g. near infra-red radiation) leads to a better correspondence between the wavelength of emitted radiation and the band-gap of the material employed in the faces of the photovoltaic cell 4, the cell efficiency may become as large as 35% to greater than 50% when compared with current commercially available solar panels that are described above. The panel will produce about 50% of the electrical power generated by other commercially available panels that employ directly illuminated single-sided photovoltaic cells and have one surface completely covered with photovoltaic cells. However, with the reduced costs of silicon associated with the designs described herein in FIGS. 1 through 9, there is a significant cost reduction in the total cost per watt of energy generated when compared with other commercially available devices that employ only single-sided photovoltaic cells that are directly illuminated.

With silicon costs constituting the predominant share of the cost of the panel, the decrease in silicon area to less than 5% (when compared with panels that are fully covered with single-sided directly illuminated photovoltaic cells) will reduce the total cost per watt of energy generated.

A system can comprise any numbers of desired panels. For example, the number of panels in a system can be greater than or equal to about 2. In one embodiment, the number of panels in a system can be greater than or equal to about 10. In another embodiment, the number of panels can be greater than or equal to about 100. In yet another embodiment, the number of panels can be greater than or equal to about 1,000.

FIG. 7 depicts three systems 400 comprising a plurality of panels 10. The depictions in FIG. 7 are exemplary and the dimensions can be varied from those depicted. The panels of FIG. 7 are only intended for purposes of demonstrating one possible design available to users of the system. Each system 400 has a height of about 1.9 meters (m) and a width of about 0.95 m. FIG. 7(a) depicts a system comprising 72 panels each having an edge of length 0.15 meters, while FIG. 7(b) depicts a system comprising 18 panels each having an edge of length 0.30 meters and FIG. 7(c) depicts a system comprising 8 panels each having an edge of length 0.45 meters.

As can be seen from the FIG. 7, the photovoltaic cells 4 that are located between two panels or those located in the interior of a panel 4 are double-sided cells, while those used on the exterior of the system 400 can be single-sided cells. FIG. 7(c) depicts the use of two types of photovoltaic cells in the panel. Double-sided photovoltaic cells 4 are used in the center of the panel while single-sided cells 204 are used on the periphery of the system 400. Double-sided cells may optionally be employed in lieu of the single-sided cells located on the periphery of the system 400.

FIGS. 8 and 9 represent different exemplary configurations where panels 10 comprising double-sided photovoltaic cells or opposingly disposed single-sided photovoltaic cells may be advantageously employed. In the FIG. 8, the panels 10 may be configured in a saw tooth configuration for use in green-houses, industrial office space, manufacturing sites, or the like. In addition, the panels can be used for green-field installation. Green-field installation is defined as one where panels can be used in remote areas where it is difficult to obtain electrical communication with existing electrical grids. An example of a green-field installation is in a desert. In such cases, the panels may be set up and can generate electricity that can be used to power other devices that are useful for existence in such remote areas. In another exemplary embodiment depicted in the FIG. 9, the panels 10 comprising double-sided photovoltaic cells or opposingly disposed single-sided photovoltaic cells can be used as façades in residential or office buildings.

In another embodiment, the disclosed designs of FIGS. 1 through 9 permit pre-assembly and pre-testing of a panel 10 comprising double-sided photovoltaic cells or the opposingly disposed single-sided photovoltaic cells. The use of adjustable screw locations permit the position of the photovoltaic cell to be adjusted and thus optimized for maximum power generation prior to installation in a residential or office building, a greenhouse or any other suitable location.

While the invention has been described with reference to exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention.

What is claimed is:

1. An article comprising:
a first panel comprising a slot; wherein the first panel comprises a first surface, a second surface and “n” sides; wherein the first surface and the second surface are opposed to each other and wherein a side has a surface that contacts the first surface and the second surface; where n is a positive integer; and
a double-sided photovoltaic cell comprising a first face and a second face disposed in the slot; wherein the double-sided photovoltaic cell is operative to receive electromagnetic radiation from the first panel on the first face and the second face simultaneously.

2. The article of claim 1, wherein the panel comprises a fluorescent dye that absorbs electromagnetic radiation and emits the radiation at larger wavelengths.

3. The article of claim 2, wherein the fluorescent dye absorbs ultraviolet radiation and emits the radiation at visible wavelengths.

4. The article of claim 1, further comprising glue disposed in the slot between the photovoltaic cell and the panel.

5. The article of claim 4, wherein the glue has a refractive index that is substantially the same as that of the panel.

6. The article of claim 4, wherein the glue protects the photovoltaic cell from abrasion and chemical degradation.

7. The article of claim 1, wherein the double-sided photovoltaic cell is fixedly attached to the panel by a bolt.

8. The article of claim 1, wherein the location of the photovoltaic cell within the slot is adjustable.

9. The article of claim 1, further comprising a photovoltaic cell disposed upon the side of the panel; wherein the photovoltaic cell is fixedly attached or matingly engaged with the side of the panel.

10. The article of claim 9, wherein the photovoltaic cell contacts the side of the panel via a glue layer disposed between the photovoltaic cell and the panel.

11. The article of claim 1, further comprising a reflective layer.

12. The article of claim 9, further comprising a reflective layer.

13. The article of claim 1, wherein the slot comprises an opening in the first surface and wherein the second surface is the surface upon which incident electromagnetic radiation directly impinges.

14. The article of claim 1, wherein the reflective layer is disposed upon a surface that is opposed to the surface upon which the electromagnetic radiation is first incident.

15. The article of claim 1, wherein the photovoltaic cell is in electrical communication with an electrical load via electrical leads.

16. The article of claim 1, wherein the panel comprises an organic polymer.

17. The article of claim 1, wherein the panel comprises an optically transparent glass.

18. The article of claim 16, wherein the organic polymer is optically transparent.

19. The article of claim 18, wherein the organic polymer is polycarbonate, polyester, polymethylmethacrylate, polystyrene, or a combination comprising at least one of the foregoing organic polymers.

20. The article of claim 18, wherein the polyester is polyethylene terephthalate, polybutylene terephthalate, poly(1,4-cyclohexane-dimethanol-1,4-cyclohexanedicarboxylate), poly(trimethylene terephthalate), poly(cyclohexanedimethanol-co-ethylene terephthalate), poly(ethylene naphthalate), poly(butylene naphthalate), or a combination comprising at least one of the foregoing polyesters.

21. The article of claim 16, wherein the organic polymer is a blend of a polycarbonate with a polyester, and wherein the polyester is a polyarylate, a polyethylene terephthalate, a polybutylene terephthalate, a poly(1,4-cyclohexane-dimethanol-1,4-cyclohexanedicarboxylate), a poly(trimethylene terephthalate), a poly(cyclohexanedimethanol-co-ethylene terephthalate), a poly(ethylene naphthalate), a poly(butylene naphthalate), or a combination comprising at least one of the foregoing polyesters.

22. The article of claim 2, wherein the fluorescent dye comprises 3-3′-diethyloxycarbocyanine-iodide, cresyl violet 670 perchlorate, anthranones and their derivatives; anthraquinones and their derivatives; croconines and their derivatives; monoazos, disazos, trisazos and their derivatives; benzimidazolones and their derivatives; diketo pyrrole pyrroles and their derivatives; dioxazines and their derivatives; diarylides and their derivatives; indanthrones and their derivatives; isoindolines and their derivatives; isoindolinones and their derivatives; naphtols and their derivatives; perinones and their derivatives; perylenes and their derivatives such as perylenic acid anhydride or perylenic acid imide; ansanthrones and their derivative; dibenzpyrenequinones and their derivatives; pyranthrones and their derivatives; bioranthorones and their derivatives; isobioranthorone and their derivatives; diphenylmethane, and triphenylmethane, type pigments; cyanine and azomethine type pigments; indigoid type pigments; bisbenzoimidazole type pigments; azulenium salts; pyrylium salts; thiapyrylium salts; benzopyrylium salts; phthalocyanines and their derivatives, pryanthrones and their derivatives; quinacidones and their derivatives; quinophthalones and their derivatives; squaraines and their derivatives; squarilyiums and their derivatives; leuco dyes and their derivatives, deuterated leuco dyes and their derivatives; leuco-azine dyes; acridines; di-and tri-arylmethane, dyes; quinoneamines; o-nitro-substituted arylidene dyes, aryl nitrone dyes, or a combination comprising at least one of the foregoing.

23. The article of claim 2, wherein the fluorescent dye is present in an amount of about 20 to about 80 wt % in the panel, based upon the total weight of the panel.

24. The article of claim 2, wherein the fluorescent dye is in the form of a quantum dot.

25. The article of claim 1, wherein the double-sided photovoltaic cell comprises monocrystalline silicon.

26. The article of claim 1, further comprising a second panel that comprises a slot; wherein the second panel comprises a first surface, a second surface and “n” sides; wherein the first surface and the second surface are opposed to each other and wherein a side has a surface that contacts the first surface and the second surface; and wherein the second panel is fixedly attached in an overlapping manner with the first panel with the first surface of the second panel in physical and intimate contact with the second surface of the first panel; and a double-sided photovoltaic cell comprising a first face and a second face disposed in the slot in the second panel; wherein the double-sided photovoltaic cell is operative to receive electromagnetic radiation from the first panel on the first face and the second face simultaneously.

27. An article comprising:
a first panel comprising a first surface, a second surface and “n” sides and having a first slot disposed therein; wherein the slot has an opening to the first surface and wherein the first surface and the second surface are opposed to each other;
a second panel comprising a first surface, a second surface and “n” sides; wherein the first surface and the second surface are opposed to each other; wherein a portion of the first surface of the second panel is in intimate overlapping contact with a portion of the second surface of the first panel; where n is a positive integer; and
a double-sided photovoltaic cell comprising a first face and a second face disposed in the first slot in the first panel; wherein the double-sided photovoltaic cell is operative to receive electromagnetic radiation from the first panel and the second panel on its first face and its second face simultaneously.

28. The article of claim 27, wherein overlapping portions of the first panel and the second panel are bonded together.

29. The article of claim 27, wherein overlapping portions of the first panel and the second panel are matingly engaged.

30. The article of claim 27, wherein overlapping portions of the first panel and the second panel are fixedly attached.

31. An article comprising:
a first panel comprising a first surface, a second surface and “n” sides; wherein the first surface and the second surface are opposed to each other;
a second panel comprising a first surface, a second surface and “n” sides; wherein the first surface and the second surface are opposed to each other; wherein either a first surface or a second surface of the first panel and the second panel are in a single plane;
a double-sided photovoltaic cell disposed between the first panel and the second panel; wherein the double-sided photovoltaic cell has a first face and a second face and wherein the first face contacts the first panel and the second face contacts the second panel.

32. The article of claim 31, wherein the first face contacts the first panel through a layer of adhesive.

33. The article of claim 32, wherein the panel has the same refractive index as the glue.

34. The article of claim 31, wherein the first panel or the second panel has a slot disposed therein; wherein the slot opens to a surface that is opposed to a surface that receives electromagnetic radiation directly; and wherein the slot is operative to receive a double-sided photovoltaic cell.

35. The article of claim 31, wherein the article is disposed upon a reflective surface; and wherein the reflective surface contacts a surface of the article that is opposed to a surface that receives electromagnetic radiation directly.

36. The article of claim 31, wherein the first and second panels comprise a fluorescent dye that absorbs electromagnetic radiation and emits the radiation at larger wavelengths.

37. The article of claim 36, wherein the fluorescent dye absorbs ultraviolet radiation and emits the radiation at visible wavelengths.

38. The article of claim 34, further comprising glue disposed in the slot between the photovoltaic cell and the panel.

39. The article of claim 38, wherein the glue has a refractive index that is substantially the same as that of the panel.

40. The article of claim 32, wherein the glue protects the photovoltaic cell from abrasion and chemical degradation.

41. The article of claim 31, further comprising a photovoltaic cell disposed upon another side of either the first or the second panel; wherein the photovoltaic cell is fixedly attached or matingly engaged with the side of the first or the second panel.

42. The article of claim 41, wherein the photovoltaic cell contacts the side of the panel via a glue layer disposed between the photovoltaic cell and the panel.

43. The article of claim 31, wherein the panel comprises an organic polymer.

44. The article of claim 31, wherein the panel comprises an optically transparent glass.

45. The article of claim 43, wherein the organic polymer is optically transparent.

46. The article of claim 45, wherein the organic polymer is polycarbonate, polyester, polymethylmethacrylate, polystyrene, or a combination comprising at least one of the foregoing organic polymers.

47. The article of claim 45, wherein the polyester is polyethylene terephthalate, polybutylene terephthalate, poly(1,4-cyclohexane-dimethanol-1,4-cyclohexanedicarboxylate), poly(trimethylene terephthalate), poly(cyclohexanedimethanol-co-ethylene terephthalate), poly(ethylene naphthalate), poly(butylene naphthalate), or a combination comprising at least one of the foregoing polyesters.

48. The article of claim 43, wherein the organic polymer is a blend of a polycarbonate with a polyester, and wherein the polyester is a polyarylate, a polyethylene terephthalate, a polybutylene terephthalate, a poly(1,4-cyclohexane-dimethanol-1,4-cyclohexanedicarboxylate), a poly(trimethylene terephthalate), a poly(cyclohexanedimethanol-co-ethylene terephthalate), a poly(ethylene naphthalate), a poly(butylene naphthalate), or a combination comprising at least one of the foregoing polyesters.

49. The article of claim 36, wherein the fluorescent dye is present in an amount of about 20 to about 80 wt % in the panel, based upon the total weight of the panel.

50. The article of claim 36, wherein the fluorescent dye is in the form of a quantum dot.

51. The article of claim 31, wherein the double-sided photovoltaic cell comprises monocrystalline silicon.

52. The article of claim 1, wherein the article is a solar panel, a roof tile, a window pane, or a building façade.

53. The article of claim 27, wherein the article is a solar panel a roof tile, a window pane, or a building façade.

54. The article of claim 31, wherein the article is a solar panel a roof tile, a window pane, or a building façade.

55. An article comprising:
a plurality of panels; wherein each panel comprises a first surface, a second surface and “n” sides; wherein the first surface and the second surface are opposed to each other; wherein either the first surface or the second surface of the plurality of panels lies substantially in a single plane; and
a double-sided photovoltaic cell or a pair of opposingly disposed single-sided photovoltaic cells disposed between a pair of panels; wherein the photovoltaic cells are operative to absorb electromagnetic radiation from the panels and to convert the electromagnetic radiation to electrical energy.

56. The article of claim 55, wherein the opposingly disposed single-sided photovoltaic cells each comprise one photoactive face, wherein the photoactive face can absorb electromagnetic radiation.

57. The article of claim 55, wherein the opposingly disposed single-sided photovoltaic cells each comprise one inactive face, wherein the inactive face does not absorb electromagnetic radiation, and wherein an inactive face is opposingly disposed towards another inactive face.

58. The article of claim 55, wherein a panel from the plurality of panels comprises perylene or a perylene derivative.

59. The article of claim 55, further comprising a reflective surface disposed upon a surface of the plurality of panels, wherein the surface of a panel that contacts the reflective surface is opposed to the surface that receives electromagnetic radiation from an external source.

60. An article comprising:
a first panel comprising a first surface, a second surface and “n” sides; wherein the first surface and the second surface are opposed to each other;
a second panel comprising a first surface, a second surface and “n” sides; wherein the first surface and the second surface are opposed to each other; wherein either a first surface or a second surface of the first panel and the second panel are in a single plane; and
a pair of opposingly disposed single-sided photovoltaic cells disposed between the first panel and the second panel; wherein the opposingly disposed single-sided photovoltaic cells each have a photoactive face and an inactive face; and further wherein the inactive faces are opposingly disposed.

61. The article of claim 60, wherein the opposingly disposed single-sided photovoltaic cells are operative to absorb electromagnetic radiation and convert it to electricity.

62. An article comprising:
a first panel comprising a slot; wherein the first panel comprises a first surface, a second surface and “n” sides; wherein the first surface and the second surface are opposed to each other and wherein a side has a surface that contacts the first surface and the second surface; where n is a positive integer; and
a pair of opposingly disposed single-sided photovoltaic cells disposed in the slot; wherein the opposingly disposed single-sided photovoltaic cells each have a photoactive face and an inactive face; and further wherein the inactive faces are opposingly disposed.

63. The article of claim 62, wherein the opposingly disposed single-sided photovoltaic cells are operative to absorb electromagnetic radiation and convert it to electricity.

64. An article comprising:
a first panel comprising a first surface, a second surface and “n” sides; wherein the first surface and the second surface are opposed to each other;
a second panel comprising a first surface, a second surface and “n” sides; wherein the first surface and the second surface are opposed to each other; wherein either a first surface or a second surface of the first panel and the second panel are in a single plane; and
a single-sided photovoltaic cell and a double-sided photovoltaic cell disposed between the first panel and the second panel; wherein the single-sided photovoltaic cell has a photoactive face and an inactive face; and wherein the double-sided photovoltaic cell has two photoactive faces; and further wherein the photoactive face of the single-sided photovoltaic cell and one photoactive face of the double-sided photoactive cell are situated in a manner that renders them operative to receive electromagnetic radiation.

65. An article comprising:
a first panel comprising a slot; wherein the first panel comprises a first surface, a second surface and “n” sides; wherein the first surface and the second surface are opposed to each other and wherein a side has a surface that contacts the first surface and the second surface; where n is a positive integer; and
a single-sided photovoltaic cell and a double-sided photovoltaic cell disposed in the slot; wherein the single-sided photovoltaic cell has a photoactive face and an inactive face; and wherein the double-sided photovoltaic cell has two photoactive faces; and further wherein the photoactive face of the single-sided photovoltaic cell and one photoactive face of the double-sided photoactive cell are situated in a manner that renders them operative to receive electromagnetic radiation.

66. A method comprising:
irradiating a panel that comprises a fluorescent dye with incident electromagnetic radiation;
absorbing the electromagnetic radiation in the fluorescent dye;
re-emitting larger wavelength radiation; wherein the re-emitted radiation has a wavelength that is larger than the wavelength of the incident electromagnetic radiation;
irradiating both faces of a double-sided photovoltaic cell with the larger wavelength radiation; and
generating an electrical current.

67. An article that employs the method of claim 66.

68. The article of claim 67, wherein the article is a solar panel.

69. A method comprising:
irradiating a panel with incident electromagnetic radiation; wherein the panel comprises a fluorescent dye;
absorbing the electromagnetic radiation in the fluorescent dye;
re-emitting larger wavelength radiation; wherein the re-emitted radiation has a wavelength that is larger than the wavelength of the incident electromagnetic radiation;
irradiating a photoactive face of a pair of opposingly disposed single-sided photovoltaic cells with the larger wavelength radiation; and
generating an electrical current.
